(19) United States
(12) Patent Application Publication
(10) Pub. No.: US 2017/0044659 A1
(43) Pub. Date: Feb. 16, 2017

(54) MAGNETRON SPUTTERING DEVICE AND METHOD USING THE SAME

(71) Applicant: BOE TECHNOLOGY GROUP CO., LTD., Beijing (CN)

(72) Inventors: Jianming SUN, Beijing (CN); Ben NIU, Beijing (CN); Zhi WANG, Beijing (CN); Xiang ZHOU, Beijing (CN)

(21) Appl. No.: 15/138,811

(22) Filed: Apr. 26, 2016

(30) Foreign Application Priority Data
Aug. 12, 2015 (CN) 201510493704.1

(51) Int. Cl. C23C 14/35; H01J 37/34; C23C 14/50; C23C 14/54; C23C 14/08

(52) U.S. Cl. CPC C23C 14/352; C23C 14/54; C23C 14/08; C23C 14/50; H01J 37/3405; H01J 37/3455; H01J 37/3429

(57) ABSTRACT

The present invention relates to a magnetron sputtering device, which comprises at least two targets, each of which is used for placing a target material for sputtering a film forming area of a same substrate; and magnetic field generating devices corresponding to the targets respectively and used for generating magnetic fields for controlling the directions of target sputtering particles. The magnetron sputtering device comprises at least two targets, and the target materials of the at least two targets are different from each other in composition, so that the purpose of doping different elements can be achieved by adjusting the proportion of the two target materials; by controlling the magnetic fields generated by the magnetic field generating devices, the sputtering speed and direction of the target materials can be controlled. The present invention also relates to a method for forming a film on a substrate by magnetron sputtering.

### FIELD OF THE INVENTION

The present invention relates to the technical field of magnetron sputtering, and specifically relates to a magnetron sputtering device and a method using the same.

### BACKGROUND OF THE INVENTION

Transparent conducting oxides (hereinafter also referred to as “TCO”) films mainly include films of oxides of In (indium), Sn (tin), Zn (zinc) and Cd (cadmium) and multiple complex oxides thereof, and have the photoelectric characteristics such as wide forbidden band, high visible spectral region transmittance and low resistance. Common IGZO (indium gallium zinc oxide) and ZnO (zinc oxide) for active layers of TFTs are applied in the display field. In practical industrial production, the characteristics of the TCO films are achieved by doping the films with certain elements, for example, Zr (zirconium)-doped ITO (indium tin oxide) films may have better photoelectric performance and stability, wherein the doping quantity of the metal element Zr most importantly influences the performance of the ITO films.

The doped TCO films in the prior art are mainly achieved by adopting magnetron sputtering devices. Specifically, a target material of a TCO doped with certain elements is sputtered onto a substrate to obtain a doped TCO film, and the result TCO films obviously have the same composition with the target material.

The inventor discovers that the prior art at least has the following problems: different films need to be doped with elements in different proportions, which requires to prepare a series of target materials with different doped element contents, so that resources are greatly wasted; and with the existing magnetron sputtering devices, doping elements continuously and uniformly in any proportion cannot be achieved, and large-area and uniform transparent conducting oxide films are difficult to form, so they can hardly be applied in the flat panel display technology.

### SUMMARY OF THE INVENTION

Technical problems to be solved by the present invention include providing a magnetron sputtering device in view of the problem of the existing magnetron sputtering devices that doping elements continuously and uniformly in any proportion cannot be achieved and large-area and uniform transparent conducting oxide films are difficult to form.

Technical solutions adopted for solving the technical problems of the present invention are as follows:

A magnetron sputtering device, including:

at least two targets, each of which is used for placing a target material for obliquely sputtering a film forming area of a same substrate; and

magnetic field generating devices corresponding to each of the targets respectively and used for generating magnetic fields for controlling the directions of target sputtering particles.

The term “oblique sputtering” used herein indicates that the targets are not parallel to the substrate but form a certain angle with the substrate for sputtering.

Preferably, the magnetic fields are variable magnetic fields, and are achieved by moving the magnetic field generating devices. More preferably, the magnetic fields are scanning magnetic fields. When the magnetic field generating devices generate the scanning magnetic fields, uniform doping and uniform deposition can be achieved.

Preferably, the target materials of the at least two targets are different from each other in material composition. Because the target materials of the at least two targets are different from each other in material composition, the purpose of doping different elements in any proportion can be achieved by adjusting the proportion of the two target materials.

Preferably, the magnetron sputtering device further includes rotating devices connected with the respective targets, which are used for driving the targets to change the angles facing the substrate, thus adjusting the orientations of the targets relative to the film forming area and a non-film forming area.

The sputtering directions of the targets is controlled by the rotating devices, thus doping of various elements can be achieved. For example, when the sputtering direction of one target is turned to the film forming area, single-target sputtering can be achieved; when the two targets are turned to the film forming area, a double-target sputtering function can be achieved, that is, when the two targets rotate to form a certain angle, the double-target sputtering function can be achieved.

Preferably, the magnetron sputtering device further includes a vacuum chamber, each of the targets and the magnetic field generating devices are arranged in the vacuum chamber, and the rotating devices are fixed on the inner walls of the vacuum chamber.

Preferably, at least one magnetic field generating device includes a magnet and a magnet control unit, and the magnet control unit is used for controlling the magnet to move relative to the target.

By controlling the relative distance between the magnet and the target, the magnitude of the magnetic field is adjusted to control the deposition rate, so that the purpose of doping in any proportion can be achieved.

Preferably, the magnet control unit includes a fixed frame on which slide rails, a first motor and a second motor are arranged, two ends of the slide rails are fixed, the magnet is arranged on the slide rails, the rail direction of the slide rails is perpendicular to the length direction of the magnet, the first motor is used for driving the magnet to move along the slide rails so as to control the scanning speed of the magnet, and the second motor is used for driving the fixed frame so as to control the magnet to away from or closer to the target.

Preferably, the magnet and the magnet control unit are fixedly arranged on one side of the target away from the film forming area.

Preferably, the target is strip-shaped, the length of the target is greater than the width of the film forming area of the substrate, and the width direction is parallel to the length direction of the target. As mentioned above, when the length of the target is greater than the width of the substrate, uniform film formation can be achieved.

Preferably, the magnetron sputtering device further includes a device capable of moving the substrate. Further preferably, the device capable of moving the substrate is a conveying device for driving the substrate to move uniformly. The substrate moves uniformly along a plane parallel to the film forming area, so the target materials can be uniformly deposited on the substrate.

Preferably, a shield is arranged on the non-film forming area of the substrate. A film can be merely formed in the film forming area by adopting the shield, so that effective sputtering can be achieved to prevent non-uniform doping caused by unnecessary sputtering.

The present invention further provides a method for forming a film on a substrate by magnetron sputtering, including the following steps: providing a substrate; providing a magnetron sputtering device including at least two targets and magnetic field generating devices corresponding to each of the targets respectively, the at least two targets are respectively used for placing a target material for sputtering a film forming area of the same substrate, and the magnetic field generating devices are used for generating magnetic fields for controlling the directions of target sputtering particles; and obliquely sputtering the film forming area of the same substrate simultaneously or sequentially by the at least two targets.

Preferably, the magnetic fields are variable magnetic fields, and are achieved by moving the magnetic field generating devices.

Preferably, the target materials of the at least two targets are different from each other in material composition.

Preferably, each of the targets is driven by the rotating devices connected with the targets to change the angles facing the substrate, thus adjusting the orientations of the targets relative to the film forming area and a non-film forming area.

Preferably, the magnetron sputtering device further includes a vacuum chamber, each of the targets and the magnetic field generating devices are arranged in the vacuum chamber, and the rotating devices are fixed on the inner walls of the vacuum chamber.

Preferably, at least one magnetic field generating device includes a magnet and a magnet control unit, and the magnet can move relative to the target under the action of the magnet control unit.

Preferably, when the film forming area is obliquely sputtered, the substrate moves uniformly along a plane parallel to the film forming area.

The magnetron sputtering device of the present invention includes at least two targets, each of which corresponds to the magnetic field generating devices respectively, and the at least two targets are used for sputtering, and the at least two target materials are doped with different elements, so that the purpose of doping different elements can be achieved by adjusting the proportion of the two target materials; by controlling the magnetic fields generated by the magnetic field generating devices, the sputtering speed and direction of the target materials are controlled, and then the purpose of uniform doping in any proportion can be achieved. The purpose of large-area uniform film formation can be achieved by moving the substrate. The magnetron sputtering device of the present invention is suitable for manufacturing various transparent conducting oxide films.

### BRIEF DESCRIPTION OF THE DRAWINGS

FIG. 1 is a structural schematic diagram of a magnetron sputtering device according to example 2 of the present invention;

FIG. 2 is a structural schematic diagram of a target of the magnetron sputtering device according to example 2 of the present invention;

wherein: 1, target; 10, film forming area; 2, magnetic field generating device; 21, magnet; 22, magnet control unit; 221, fixed frame; 222, slide rail; 223, first motor; 224, second motor; 3, rotating device; 4, substrate; 5, conveying device; 51, shield.

### DESCRIPTION OF THE PREFERRED EMBODIMENT

In order that those skilled in the art better understand the technical solutions of the present invention, the present invention will be further described in detail below in combination with accompanying drawings and specific examples.

### Example 1

This example provides a magnetron sputtering device, including:

at least two targets, each of which is used for placing a target material for obliquely sputtering a film forming area of a same substrate; and

magnetic field generating devices corresponding to each of the targets respectively and used for generating magnetic fields for controlling the directions of target sputtering particles.

The magnetron sputtering device of the present invention includes at least two targets, each of which corresponds to the magnetic field generating devices respectively, and the at least two targets are used for sputtering, and the target materials of the at least two target are different from each other in material composition, so that the purpose of doping different elements is achieved by adjusting the proportion of the two target materials; by controlling the magnetic fields generated by the magnetic field generating devices, the sputtering speed and direction of the target materials are controlled, and then the purpose of uniform doping in any proportion can be achieved. The purpose of large-area uniform film formation can be achieved by moving the substrate. The magnetron sputtering device of the present invention is suitable for manufacturing various transparent conducting oxide films.

### Example 2

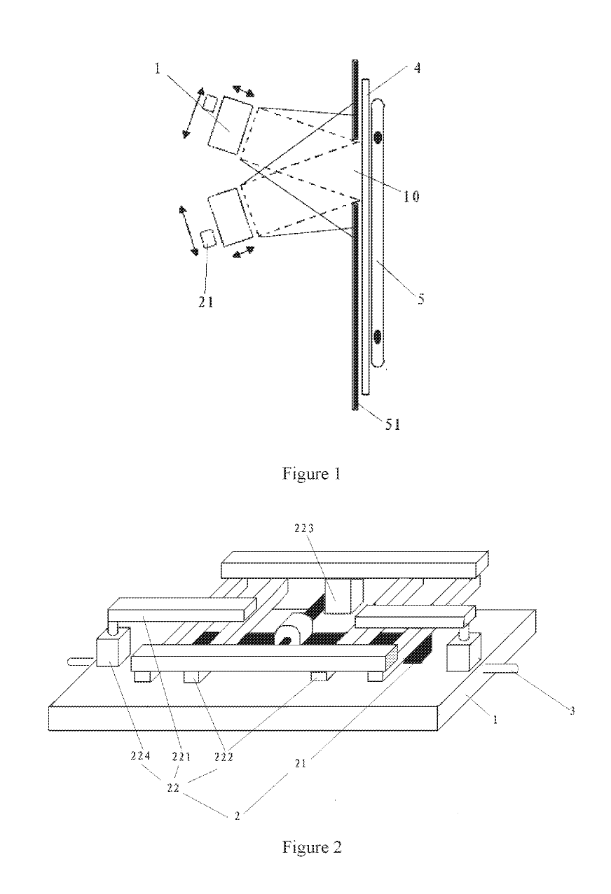

As shown in FIGS. 1-2, this example provides a magnetron sputtering device, including:

at least two targets 1, each of which is used for placing a target material for obliquely sputtering a film forming area 10 of a same substrate 4; and

magnetic field generating devices 2 corresponding to each of the targets 1 respectively and used for generating magnetic fields for controlling the directions of target sputtering particles.

The magnetic fields are variable magnetic fields, and are achieved by moving the magnetic field generating devices. Further preferably, the magnetic fields are scanning magnetic fields.

Preferably, the magnetron sputtering device further includes rotating devices 3 connected with the respective targets 1, the rotating devices are used for driving the targets 1 to change the angles facing the substrate 4, thus adjusting the orientations of the targets 1 relative to the film forming area 10 and a non-film forming area.

Preferably, the target materials of the at least two targets 1 are different from each other in material composition.

That is to say, the sputtering directions of the targets is controlled by the rotating devices 3, thus doping of various elements can be achieved. For example, when the sputtering direction of one target 1 is turned to the film forming area 10, single-target sputtering can be achieved; when the two targets 1 are both turned to the film forming area 10, a double-target sputtering function can be achieved, that is, when the two targets rotate to form a certain angle, the double-target sputtering function can be achieved.

Preferably, the magnetron sputtering device further includes a vacuum chamber (not shown in the figures), each of the targets 1 and the magnetic field generating devices 2 are arranged in the vacuum chamber, and the rotating devices 3 are fixed on the inner walls of the vacuum chamber.

Preferably, at least one magnetic field generating device 2 includes a magnet 21 and a magnet control unit 22, the magnet control unit 22 is used for controlling the magnet 21 to move relative to the target 1.

That is to say, the magnitude of the magnetic field can be adjusted by controlling the relative distance between the magnet 21 and the target 1 to control the deposition rate, so as to control the doping proportion.

Preferably, the magnet control unit 22 includes a fixed frame 221 on which slide rails 222, a first motor 223 and a second motor 224 are arranged, two ends of the slide rails 222 are fixed, the magnet 21 is arranged on the slide rails 222, the rail direction of the slide rails 222 is perpendicular to the length direction of the magnet 21, the first motor 223 is used for driving the magnet 21 to move along the slide rails 222 so as to adjust the scanning speed of the magnet 21, and the second motor 224 drives the fixed frame 221 so as to control the magnet 21 to away from or closer to the target 1.

More specifically, the first motor 223 drives a screw, so that the screw drives the magnet 21 to move along the slide rails 222.

Preferably, the magnet 21 and the magnet control unit 22 are fixedly arranged on one side of the target 1 away from the film forming area 10.

Preferably, the length of the target 1 is greater than the width of the film forming area 10 of the substrate 4, and the width direction is parallel to the length direction of the target 1.

Preferably, the magnetron sputtering device further includes a device capable of moving the substrate 4. Further preferably, the device capable of moving the substrate 4 is a conveying device 5 for driving the substrate to move uniformly.

That is to say, the area of the target 1 in the prior art is generally greater than that of the substrate 4, so as to ensure that the target materials can be sputtered on the substrate 4 anywhere. In this example, the target 1 is strip-shaped and narrow, and the area of the target is far smaller than that of the substrate 4; the conveying device 5 drives the substrate 4 to move uniformly, so that the substrate 4 is uniformly sputtered to form a large-area film; generally, the length of the target is not limited in particular, as long as the length of the target is greater than the width of the substrate 4. In this case, not only can the target materials be saved, but also a film deposited uniformly can be obtained by continuous sputtering. Due to the fact that the magnetron sputtering device according to the example could save the target materials, thus it particularly suitable for large-area doped co-sputtering and continuous uniform film formation. The film manufactured thereby is more suitable for large-sized display devices.

Preferably, a shield 51 may be arranged on the non-film forming area of the substrate 4.

That is to say, as shown in FIG. 1, the area shown in solid lines is an area actually available for sputtering, the area shown in dotted lines is used as the film forming area, and in order to avoid unnecessary sputtering, the shield 51 is arranged on other non-film forming area to prevent non-uniform doping caused by unnecessary sputtering.

### Example 3

This example provides a method for forming a film on a substrate by magnetron sputtering, including the following steps:

providing a substrate 4;

providing a magnetron sputtering device including at least two targets 1 and magnetic field generating devices 2 corresponding to each of the targets 1 respectively, the at least two targets 1 are respectively used for placing a target material for sputtering a film forming area 10 of the same substrate 4, and the magnetic field generating devices 2 are used for generating magnetic fields for controlling the directions of target sputtering particles; and

obliquely sputtering the film forming area 10 of the same substrate 4 simultaneously or sequentially by the at least two targets 1.

Preferably, the magnetic fields are variable magnetic fields, and are achieved by moving the magnetic field generating devices 2.

Preferably, the target materials of the at least two targets 1 are different from each other in material composition.

Preferably, each of the targets 1 is driven by the rotating devices 3 connected with the targets 1 to change the angles facing the substrate 4, thus adjusting the orientations of the targets 1 relative to the film forming area 10 and a non-film forming area.

Preferably, the magnetron sputtering device further includes a vacuum chamber, each of the targets 1 and the magnetic field generating devices 2 are arranged in the vacuum chamber, and the rotating devices 3 are fixed on the inner walls of the vacuum chamber.

Preferably, the magnet 21 moves relative to the target 1 under the action of the magnet control unit 22.

Preferably, the substrate 4 moves uniformly along a plane parallel to the film forming area 10 when the film forming area 10 is obliquely sputtered.

It could be understood that the above examples are merely exemplary examples adopted for describing the principle of the present invention, but the present invention is not limited thereto. Various variations and improvements may be made for those of ordinary skill in the art without departing from the spirit and essence of the present invention, and these variations and improvements shall also be encompassed within the protection scope of the present invention.

1. A magnetron sputtering device, including:
at least two targets, each of which is used for placing a target material for sputtering a film forming area of a same substrate; and
magnetic field generating devices corresponding to each of the targets respectively and used for generating magnetic fields for controlling the directions of target sputtering particles.

2. The magnetron sputtering device of claim 1, wherein the magnetic fields are variable magnetic fields, and are achieved by moving the magnetic field generating devices.

3. The magnetron sputtering device of claim 2, wherein the magnetic fields are scanning magnetic fields.

4. The magnetron sputtering device of claim 1, wherein the target materials of the at least two targets are different from each other in material composition.

5. The magnetron sputtering device of claim 1, wherein it further includes rotating devices connected with the respective targets, which are used for driving the targets to change the angles facing the substrate, thus adjusting the orientations of the targets relative to the film forming area and a non-film forming area.

6. The magnetron sputtering device of claim 5, wherein the magnetron sputtering device further includes a vacuum chamber, each of the targets and the magnetic field generating devices are arranged in the vacuum chamber, and the rotating devices are fixed on the inner walls of the vacuum chamber.

7. The magnetron sputtering device of claim 1, wherein at least one magnetic field generating device comprises a magnet and a magnet control unit, and the magnet control unit is used for controlling the magnet to move relative to the target.

8. The magnetron sputtering device of claim 7, wherein the magnet control unit comprises a fixed frame on which slide rails, a first motor and a second motor are arranged, two ends of the slide rails are fixed, the magnet is arranged on the slide rails, the rail direction of the slide rails is perpendicular to the length direction of the magnet, the first motor is used for driving the magnet to move along the slide rails so as to control the scanning speed of the magnet, and the second motor is used for driving the fixed frame so as to control the magnet to away from or closer to the target.

9. The magnetron sputtering device of claim 7, wherein the magnet and the magnet control unit are fixedly arranged on one side of the target away from the film forming area.

10. The magnetron sputtering device of claim 1, wherein the target is strip-shaped, the length of the target is greater than the width of the film forming area of the substrate, and the width direction is parallel to the length direction of the target.

11. The magnetron sputtering device of claim 1, wherein the magnetron sputtering device further comprises a device capable of moving the substrate.

12. The magnetron sputtering device of claim 11, wherein the device capable of moving the substrate is a conveying device for driving the substrate to move uniformly.

13. The magnetron sputtering device of claim 1, wherein a shield is arranged on the non-film forming area of the substrate.

14. A method for forming a film on a substrate by magnetron sputtering, comprising the following steps:
providing a substrate;
providing a magnetron sputtering device comprising at least two targets and magnetic field generating devices corresponding to each of the targets respectively, the at least two targets are respectively used for placing a target material for sputtering a film forming area of the same substrate, and the magnetic field generating devices are used for generating magnetic fields for controlling the directions of target sputtering particles; and
obliquely sputtering the film forming area of the same substrate simultaneously or sequentially by the at least two targets.

15. The method of claim 14, wherein the magnetic fields are variable magnetic fields, and are achieved by moving the magnetic field generating devices.

16. The method of claim 14, wherein the target materials of the at least two targets are different from each other in material composition.

17. The method of claim 14, wherein each of the targets is driven by the rotating devices connected with the targets to change the angles facing the substrate, thus adjusting the orientations of the targets relative to the film forming area and a non-film forming area.

18. The method of claim 17, wherein the magnetron sputtering device further comprises a vacuum chamber, each of the targets and the magnetic field generating devices are arranged in the vacuum chamber, and the rotating devices are fixed on the inner walls of the vacuum chamber.

19. The method of claim 17, wherein at least one magnetic field generating device comprises a magnet and a magnet control unit, and the magnet can move relative to the target under the action of the magnet control unit.

20. The method of claim 14, wherein when the film forming area is obliquely sputtered, the substrate moves uniformly along a plane parallel to the film forming area.
